(19) United States
(12) Patent Application Publication
(10) Pub. No.: US 2008/0067589 A1
(43) Pub. Date: Mar. 20, 2008

(54) Transistor having reduced channel dopant fluctuation

(76) Inventors: Akira Ito, Irvine, CA (US); Henry Kuoshun Chen, Irvine, CA (US); Guang-Jye Shiau, Irvine, CA (US)

Correspondence Address: FARJAMI & FARJAMI LLP, 26522 LA ALAMEDA AVENUE, SUITE 360, MISSION VIEJO, CA, 92691, US

(21) Appl. No.: 11/524,721

(22) Filed: Sep. 20, 2006

(51) Int. Cl. H01L 29/76

(52) U.S. Cl. 257/344

(57) ABSTRACT

According to one exemplary embodiment, a transistor includes a source and a drain separated by a channel. The transistor further includes a gate dielectric layer situated over the channel. The channel is situated in a well formed in a substrate. A pocket implant is not formed between the source and the drain so as to reduce dopant fluctuation in the channel, thereby reducing transistor mismatch. According to this exemplary embodiment, an LDD implant is not formed between the source and the drain so as to further reduce the dopant fluctuation in the channel.

### BACKGROUND OF THE INVENTION

1. Field of the Invention

The present invention is generally in the field of semiconductors. More particularly, the invention is in the field of semiconductor transistor structures.

2. Background Art

A conventional transistor, such as a conventional Metal Oxide Semiconductor Field Effect Transistor (MOSFET), typically includes lightly doped drain (LDD) implants to reduce undesirable hot carrier injection and “pocket implants” to reduce undesirable channel leakage between source and drain. As the transistor is scaled down to smaller dimensions in advanced process technologies, the length of the channel formed between the transistor's source and drain decreases, which can cause increased channel leakage. In the conventional transistor, channel leakage can be improved by increasing the doping level of the pocket implants that are formed adjacent to the source and the drain of the transistor.

However, pocket and LDD implants that are typically utilized in a conventional transistor, such as a conventional MOSFET, can cause increased dopant fluctuation in the channel of the transistor, which can increase “transistor mismatch.” In the present application, “transistor mismatch” refers to measurable differences in transistor electrical characteristics (e.g. threshold voltage (VT), saturation drive current (Idsat), and transconductance (gm)) that are otherwise identical in design and layout. Increased transistor mismatch can cause a conventional transistor, such as a conventional MOSFET, to become more difficult to match in analog circuits that require accurate transistor matching, such as digital-to-analog converters (DAC), analog-to-digital converters (ADC), current mirrors, analog comparators, and sense amplifiers in memory arrays, for example.

### SUMMARY OF THE INVENTION

A transistor, substantially as shown in and/or described in connection with at least one of the figures, as set forth more completely in the claims.

### BRIEF DESCRIPTION OF THE DRAWINGS

FIG. 1 illustrates a cross sectional view of an exemplary structure including a conventional exemplary transistor.

FIG. 2 illustrates a cross sectional view of an exemplary structure including an exemplary transistor in accordance with one embodiment of the present invention.

FIG. 3 shows a flowchart illustrating the steps taken to implement an embodiment of the present invention.

FIG. 4 illustrates a diagram of an exemplary electronic system including an exemplary chip or die utilizing one or more transistors in accordance with one embodiment of the present invention.

### DETAILED DESCRIPTION OF THE INVENTION

The present invention is directed to a transistor having reduced channel dopant fluctuation. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings.

The present invention achieves an innovative transistor having reduced channel dopant fluctuation. As will be discussed in detail below, the present invention advantageously a transistor having decreased transistor mismatch by reducing dopant fluctuation in the transistor's channel. It is noted that although an NMOS transistor is utilized to illustrate the invention, the invention can also be applied to a PMOS transistor.

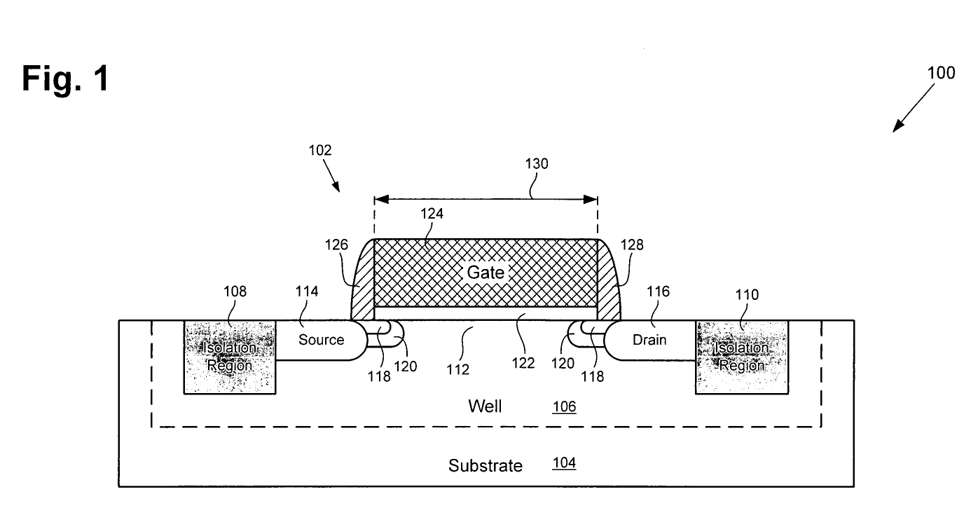

FIG. 1 shows a cross-sectional view of an exemplary structure including a conventional exemplary transistor. Structure 100 includes conventional transistor 102, substrate 104, well 106, and isolation regions 108 and 110. Conventional transistor 102 includes channel 112, source 114, drain 116, LDD (lightly doped drain) implant 118, pocket implant 120, gate dielectric (or “gate oxide”) layer 122, gate 124, and spacers 126 and 128. Conventional transistor 102, which is situated over substrate 104, can be a MOSFET, such as an NMOS transistor, for example.

As shown in FIG. 1, well 106 is situated in substrate 104, which can be a lightly doped P type substrate, for example. Well 106 can be, for example, a lightly doped P type well (i.e. a P well), which has a greater doping level than substrate 104. Also shown in FIG. 1, isolation regions 108 and 110 are situated in substrate 104 and provide electrical isolation between transistor 102 and other devices situated over substrate 104. Isolation regions 108 and 110 can comprise silicon oxide and can be shallow trench isolation (STI) regions, for example. Further shown in FIG. 1, gate dielectric layer 122 is situated over channel 112, which is formed in substrate 104. Gate dielectric layer 122 can comprise silicon oxide, for example, and can be formed over channel 112 by using a suitable deposition process or thermal oxidation process.

Also shown in FIG. 1, gate 124 is situated over gate dielectric layer 122 and can comprise polycrystalline silicon (polysilicon) or other suitable conductive material. Gate 124 can be formed, for example, by depositing a layer of polysilicon over gate dielectric layer 122 by using a chemical vapor deposition (CVD) process or other suitable deposition process and appropriately patterning the layer of polysilicon. Further shown in FIG. 1, spacers 126 and 128 are situated adjacent to the respective sidewalls of gate 124 and can comprise a dielectric material such as silicon oxide or silicon nitride. Spacers 126 and 128 can be formed by depositing a conformal dielectric layer over gate 124 and etching back the dielectric layer.

Also shown in FIG. 1, LDD implant 118 is situated in well 106 adjacent to the sidewalls of gate 124 and can comprise a lightly doped N type region, for example. LDD implant 118 can be formed in a conventional CMOS process by implanting a N type dopant, for example, in well 106 adjacent to the sidewalls of gate 124 prior to formation of spacers 126 and 128. Further shown in FIG. 1, pocket implant 120 is situated under gate oxide dielectric 122 in well 106 and can comprise a P type region, for example, which has a greater doping level than well 106. Pocket implant 120 can be formed in the conventional CMOS process by implanting a P type dopant, for example, in well 106 at a suitable angle with respect to the top surface of substrate 104 so as to form pocket implant 120 under gate dielectric layer 122 prior to formation of spacers 126 and 128 and after formation of LDD implant 118. Also shown in FIG. 1, source 114 and drain 116 are situated in well 106 adjacent to respective spacers 126 and 128 and can comprise heavily doped N type regions, for example. Source 114 and drain 116 can be formed by implanting a large dose of N type dopant, for example, in well 106 adjacent to spacers 126 and 128.

In conventional transistor 102, LDD implant 118, which has the same conductivity type as source 114 and drain 116, is utilized to reduce the hot carrier effect, wherein hot carriers (e.g. electrons) are injected into gate 124 via gate dielectric layer 122. The hot carriers that are injected as a result of the hot carrier effect can cause damage to gate 124. Pocket implant 120, which has an opposite conductivity type as source 114 and drain 116, is utilized in conventional transistor 102 to reduce channel leakage between source 114 and drain 116. However, pocket implant 120 and LDD implant 118 can cause dopant fluctuation in channel 112 as a result of implant dose, energy, and angle. As conventional transistor 102 is scaled down to smaller dimensions in advanced process technologies, length 130 of gate 124 is reduced, which reduces the length of channel 112 (i.e. the separation between source 114 and drain 116). As channel length is reduced, channel leakage between source 114 and drain 116 can increase. In conventional transistor 102, the increased source-to-drain leakage can be reduced by increasing the dopant level of pocket implant 120. However, increasing the dopant level of pocket implant 120 causes a further increase in dopant fluctuation in channel 112.

As discussed above, transistor mismatch, which determines how accurately the transistor can be matched in a circuit, is dependent on dopant fluctuation in the channel. Increased channel dopant fluctuation can increase transistor mismatch and, thereby, cause the transistor to become more difficult to match in circuits that require accurately transistor matching, such as DACs, ADCs, current mirrors, analog comparators, sense amplifiers in memory arrays, and other precision analog circuits. Thus, LDD implant 118 and pocket implant 120 can increase transistor mismatch by increasing channel dopant fluctuation, which can cause conventional transistor 102 to become more difficult to match in analog circuits that require accurate transistor matching, such as the analog circuits discussed above.

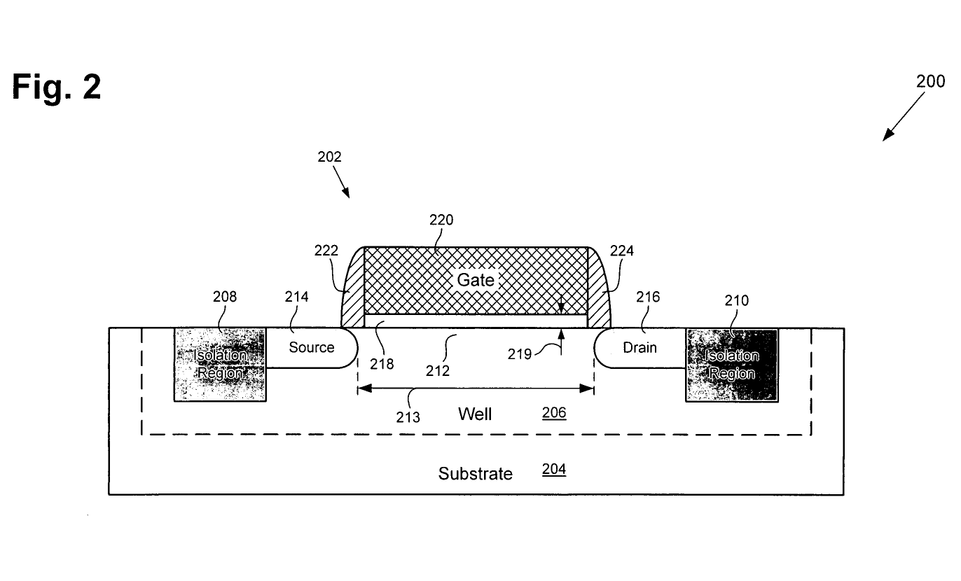

FIG. 2 shows a cross-sectional view of an exemplary structure including an exemplary transistor in accordance with one embodiment of the present invention. Structure 200 includes transistor 202, substrate 204, well 206, and isolation regions 208 and 210. Transistor 202 includes channel 212, source 214, drain 216, gate dielectric (or “gate oxide”) layer 218, gate 220, and spacers 222 and 224. Transistor 202, which is situated over substrate 204, can be a MOSFET, such as an NMOS or a PMOS transistor, formed in accordance with an embodiment of the invention as described below.

As shown in FIG. 2, well 206 is situated in substrate 204, which can be a lightly doped P type substrate, for example. Well 206 can be, for example, a lightly doped P type well (i.e. a P well) having a greater doping level than substrate 204. Also shown in FIG. 2, isolation regions 208 and 210 are situated in substrate 204 and provide electrical isolation between transistor 202 and other devices situated over substrate 204. Isolation regions 208 and 210 can comprise silicon oxide and can be shallow trench isolation (STI) regions, for example. Further shown in FIG. 2, gate dielectric layer 218 is situated over channel 212, can comprise silicon oxide, nitridized silicon oxide, or other suitable dielectric material, and has thickness 219. Gate dielectric layer 218 can be formed by using a CVD process, thermal oxidation process, or other suitable deposition process to deposit a layer of gate oxide over substrate 204. Channel 212 is situated under gate dielectric layer 218 in well 206, extends between source 214 and drain 216, and has length 213.

Also shown in FIG. 2, gate 220 is situated over gate dielectric layer 218 and can comprise polysilicon or other suitable conductive material. Gate 220 can be formed by using a CVD process or other suitable deposition process to deposit a layer of polysilicon over gate dielectric layer 218 and appropriately patterning the polysilicon layer. Further shown in FIG. 2, spacers 222 and 224 are situated adjacent to respective sidewalls of gate 220 and can comprise a dielectric material such as silicon oxide or silicon nitride, for example. Spacers 222 and 224 can be formed by depositing a conformal dielectric layer over gate 220 by using a CVD process or other suitable deposition process and etching back the conformal dielectric layer in a suitable etch back process. Also shown in FIG. 2, source 214 and drain 216 are situated in well 206 adjacent to respective spacers 222 and 224 and can comprise heavily doped N type regions, for example. Source 214 and drain 216 can be formed by implanting a large dose of N type dopant, for example, in well 206 adjacent to respective spacers 222 and 224.

In the present embodiment, transistor 202 does not include LDD and pocket implants situated between source 214 and drain 216 in well 206. Thus, during formation of transistor 202, LDD and pocket implants, such as LDD implant 118 and pocket implant 120 in conventional transistor 102 in FIG. 1, are not formed in well 206 adjacent to the sidewalls of gate 220. For example, LDD and pocket implant steps can be passed over (i.e. skipped) in the invention's process flow. In one embodiment, LDD and pocket implants can be “masked out” for one or more transistors, such as transistor 202, that are selected to not receive LDD and pocket implants on a semiconductor, while LDD and pocket implants can be provided for other transistors on the semiconductor die. In one embodiment, the invention's transistor can include an LDD implant without a pocket implant, where the LDD implant is formed in a well adjacent to the sidewalls of the gate prior to formation of gate spacers. By eliminating a pocket implant, the invention achieves a transistor (e.g. transistor 202) having a reduction in dopant fluctuation in the transistor's channel (e.g. channel 212). Also, by eliminating an LDD implant, the present embodiment of the invention achieves a transistor that provides a further reduction in channel dopant fluctuation.

In one embodiment, the invention's transistor (e.g. transistor 202 in FIG. 2) can be utilized in an analog circuit having a DC power supply voltage (VDD) that does not exceed approximately 1.2 volts. For example, the DC power supply voltage can be between approximately 1.0 volt and approximately 1.2 volts. In that embodiment, the invention's transistor can have a gate oxide layer having a thickness (e.g. thickness 219 in FIG. 2) of between 20.0 Angstroms and 30.0 Angstroms, a channel length (e.g. channel length 213) of between 0.1 micron and 0.9 micron, and an operating DC voltage of between 0.6 volts and 0.9 volts inside the analog circuit.

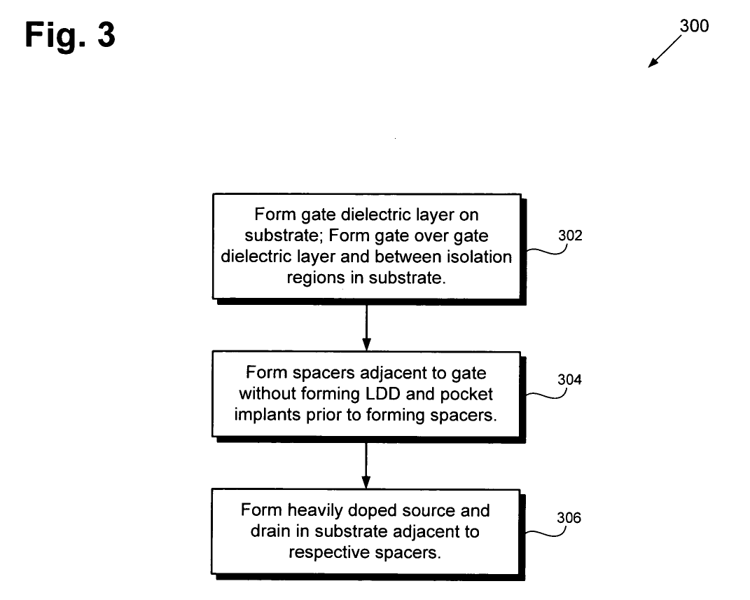

FIG. 3 shows a flowchart illustrating an exemplary method according to an embodiment of the present invention. Certain details and features have been left out of flowchart 300 that are apparent to a person of ordinary skill in the art. For example, a step may consist of one or more substeps or may involve specialized equipment or materials, as known in the art.

Referring now to step 302 of flowchart 300 in FIG. 3, gate dielectric layer 218 is formed over substrate 204 and gate 220 is formed over gate dielectric layer 218 and between isolation regions 208 and 210 in substrate 204. Gate dielectric layer 218 can be formed, for example, by depositing a layer of gate oxide, such as silicon oxide or nitridized silicon oxide, over substrate 204 by using a CVD process or thermal oxidation process. Gate 220 can be formed, for example, by using a CVD process to deposit a layer of polysilicon over gate dielectric layer 218 and appropriately patterning the polysilicon layer.

At step 304 of flowchart 300, spacers 222 and 224 are formed adjacent to gate 220 without forming LDD and pocket implants prior to forming spacers 222 and 224. Spacers 222 and 224 can be formed by depositing a conformal dielectric layer over gate 220 by using a CVD process and etching back the conformal dielectric layer in a suitable etch back process, for example. In the present embodiment, LDD and pocket implants, such as LDD and pocket implants 118 and 120 in transistor 102 in FIG. 1, are not formed in well 106 adjacent to the sidewalls of gate 220 prior to forming spacers 222 and 224. For example, LDD and pocket implant steps can be skipped in the invention's process flow. At step 306 of flowchart 300, source 214 and drain 216 and be formed in well 206 in substrate 204 adjacent to respective spacers 222 and 224. For example, source 214 and drain 216 can be formed by implanting a large dose of N type dopant, for example, in well 206 adjacent to respective spacers 222 and 224.

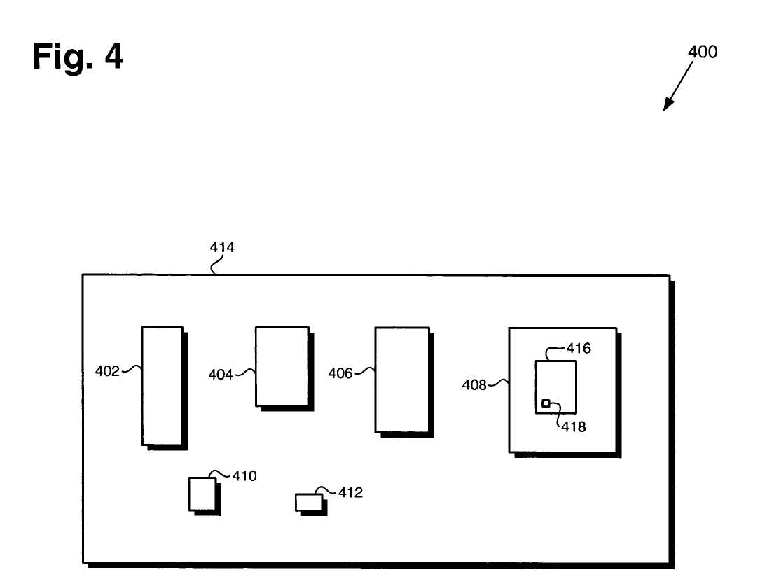

FIG. 4 illustrates a diagram of an exemplary electronic system including an exemplary chip or die utilizing one or more transistors in accordance with one embodiment of the present invention. Electronic system 400 includes exemplary modules 402, 404, and 406, IC chip or semiconductor die 408, discrete components 410 and 412, residing in and interconnected through printed circuit board (PCB) 414. In one embodiment, electronic system 400 may include more than one PCB. IC chip 408 includes circuit 416, which utilizes one or more of the invention's transistors designated by numeral 418.

As shown in FIG. 4, modules 402, 404, and 406 are mounted on PCB 414 and can each be, for example, a central processing unit (CPU), a graphics controller, a digital signal processor (DSP), an application specific integrated circuit (ASIC), a video processing module, an audio processing module, an RF receiver, an RF transmitter, an image sensor module, a power control module, an electro-mechanical motor control module, or a field programmable gate array (FPGA), or any other kind of module utilized in modern electronic circuit boards. PCB 414 can include a number of interconnect traces (not shown in FIG. 4) for interconnecting modules 402, 404, and 406, discrete components 410 and 412, and IC chip 408.

Also shown in FIG. 4, IC chip 408 is mounted on PCB 414 and can be, for example, any chip utilizing an embodiment of the invention's transistor. In one embodiment, IC chip 408 may not be mounted on PCB 414, and may be interconnected with other modules on different PCBs. As stated above, circuit 416 is situated in IC chip 408 and includes one or more embodiments of the invention's transistor(s) 418. Further shown in FIG. 4, discrete components 410 and 412 are mounted on PCB 414 and can each be, for example, a discrete filter, such as one including a BAW or SAW filter or the like, a power amplifier or an operational amplifier, a semiconductor device, such as a transistor or a diode or the like, an antenna element, an inductor, a capacitor, or a resistor. Discrete components 410 and 412 may themselves utilize one embodiment of the invention's transistor.

Electronic system 400 can be utilized in, for example, a wired communications device, a wireless communications device, a cell phone, a switching device, a router, a repeater, a codec, a LAN, a WLAN, a Bluetooth enabled device, a digital camera, a digital audio player and/or recorder, a digital video player and/or recorder, a computer, a monitor, a television set, a satellite set top box, a cable modem, a digital automotive control system, a digitally-controlled home appliance, a printer, a copier, a digital audio or video receiver, an RF transceiver, a personal digital assistant (PDA), a digital game playing device, a digital testing and/or measuring device, a digital avionics device, a medical device, or a digitally-controlled medical equipment, or in any other kind of system, device, component or module utilized in modern electronics applications.

As discussed above, dopant fluctuation in the channel of a transistor, such as a MOSFET, can increase transistor mismatch, which refers to measurable differences in transistor electrical characteristics (e.g. VT (threshold voltage), Idsat (saturation drive current), and gm (transconductance)) between otherwise “matched pairs” of transistors. Thus, by reducing channel dopant fluctuation, the invention achieves a transistor having reduced transistor mismatch. As a result, the invention achieves a transistor that can be advantageously utilized in analog circuits that required accurate transistor matching, such as such as DACs, ADCs, current mirrors, analog comparators, and sense amplifiers in SRAM and other memory arrays, for example. By reducing transistor mismatch, the invention achieves a transistor that can be scaled down to a desirably small channel length, thereby allowing an analog circuit that utilizes the invention's transistor(s) to consume less area on a semiconductor die.

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, a transistor having reduced channel dopant fluctuation has been described.

1. A transistor comprising:
a source and a drain separated by a channel;
a gate dielectric layer situated over said channel;
wherein a pocket implant is not formed around said source and said drain so as to reduce dopant fluctuation in said channel, thereby reducing transistor mismatch.

2. The transistor of claim 1, wherein an LDD implant is not formed around said source and said drain so as to further reduce said dopant fluctuation in said channel.

3. The transistor of claim 1, wherein said transistor is utilized in an analog circuit having a DC power supply voltage that does not exceed approximately 1.2 volts.

4. The transistor of claim 3, wherein said gate dielectric layer has a thickness of between 20.0 Angstroms and 30.0 Angstroms, said channel has a length of between 0.1 micron and 0.9 micron, and said transistor has an operating DC voltage of between 0.6 volts and 0.9 volts inside said analog circuit.

5. The transistor of claim 1, wherein said transistor is utilized in a circuit selected from the group consisting of an analog-to-digital converter (ADC), a digital-to-analog converter (DAC), a comparator, a current mirror, and a sense amplifier in a memory array.

6. The transistor of claim 1, wherein said transistor is a MOSFET.

7. The transistor of claim 1, wherein said channel is situated in a well formed in a substrate.

8. A method of forming a transistor, said method comprising steps of:
forming a gate over a substrate;
forming spacers adjacent to respective sides of said gate;
forming a source and a drain in said substrate adjacent to said spacers, respectively, said source and said drain being separated by a channel;
wherein a pocket implant is not formed around said source and said drain so as to reduce dopant fluctuation in said channel, thereby reducing transistor mismatch.

9. The method of claim 8, wherein an LDD implant is not formed around said source and said drain so as to further reduce said dopant fluctuation in said channel.

10. The method of claim 10 further comprising a step of forming a gate dielectric layer over said substrate prior to said step of forming said gate.

11. The method of claim 10, wherein said transistor is utilized in an analog circuit having a DC power supply voltage that does not exceed approximately 1.2 volts.

12. The method of claim 11, wherein said gate dielectric layer has a thickness of between 20.0 Angstroms and 30.0 Angstroms, said channel has a length of between 0.1 micron and 0.9 micron, and said transistor has an operating DC voltage of between 0.6 volts and 0.9 volts inside said analog circuit.

13. The method of claim 8, wherein said transistor is utilized in a circuit selected from the group consisting of an analog-to-digital converter (ADC), a digital-to-analog converter (DAC), a comparator, a current mirror, and a sense amplifier in a memory array.

14. The method of claim 8, wherein said transistor is a MOSFET.

15. An electronic system comprising:
a die, said die comprising at least one transistor, said at least one transistor comprising:
a source and a drain separated by a channel;
a gate dielectric layer situated over said channel;
wherein a pocket implant is not formed around said source and said drain so as to reduce dopant fluctuation in said channel, thereby reducing transistor mismatch.

16. The electronic system of claim 15, wherein said at least one transistor does not include an LDD implant around said source and said drain so as to further reduce said dopant fluctuation in said channel.

17. The electronic system of claim 16, wherein said at least one transistor is utilized in an analog circuit having a DC power supply voltage that does not exceed approximately 1.2 volts.

18. The electronic system of claim 17, wherein said gate dielectric layer has a thickness of between 20.0 Angstroms and 30.0 Angstroms, said channel has a length of between 0.1 micron and 0.9 micron, and said at least one transistor has an operating DC voltage of between 0.6 volts and 0.9 volts inside said analog circuit.

19. The electronic system of claim 15, wherein said at least one transistor is utilized in a circuit selected from the group consisting of an analog-to-digital converter (ADC), a digital-to-analog converter (DAC), a comparator, a current mirror, and a sense amplifier in a memory array.

20. The electronic system of claim 15, wherein said electronic system is selected from the group consisting of a wired communications device, a wireless communications device, a cell phone, a switching device, a router, a repeater, a codec, a LAN, a WLAN, a Bluetooth enabled device, a digital camera, a digital audio player and/or recorder, a digital video player and/or recorder, a computer, a monitor, a television set, a satellite set top box, a cable modem, a digital automotive control system, a digitally-controlled home appliance, a printer, a copier, a digital audio or video receiver, an RF transceiver, a personal digital assistant (PDA), a digital game playing device, a digital testing and/or measuring device, a digital avionics device, a medical device, and a digitally-controlled medical equipment.
